(19) United States
(12) Patent Application Publication
(10) Pub. No.: US 2025/0334645 A1
(43) Pub. Date: Oct. 30, 2025

(54) METHOD, DEVICE, AND STORAGE MEDIUM FOR BATTERY PHYSICAL SELF-DISCHARGE DETECTION

(71) Applicant: SEMIGHT INSTRUMENTS CO., LTD, Suzhou (CN)

(72) Inventors: Zhe LIAN, Suzhou (CN); Chaosong PAN, Suzhou (CN); Jianjun HUANG; Haiyang HU, Suzhou (CN)

(21) Appl. No.: 19/264,854

(22) Filed: Jul. 10, 2025

Related U.S. Application Data
(63) Continuation of application No. PCT/CN2024/075429, filed on Feb. 2, 2024.

(30) Foreign Application Priority Data
Feb. 10, 2023 (CN) 202310101391.5

(51) Int. Cl. G01R 31/392; G01R 31/36; G01R 31/367; G01R 31/3835; G01R 31/389

(52) U.S. Cl. CPC G01R 31/392; G01R 31/3646; G01R 31/367; G01R 31/3835; G01R 31/389

(57) ABSTRACT

A method, device, and medium for battery physical self-discharge detection are provided. Related to the field of battery monitoring technology and used to detect whether a battery has physical self-discharge, the present disclosure addresses issues of long testing time and difficulty in implementation with current self-discharge detection practice, provides a battery physical self-discharge testing method, leverages frequency response characteristics of battery physical self-discharge and chemical self-discharge to perform self-discharge detection, and rapidly screens whether the battery has physical self-discharge by monitoring a battery voltage change trend. The testing time is short for determining whether a battery has physical self-discharge. It does not need low-temperature storage, reduces implementation difficulty and cost, and better meets requirements of practical battery self-discharge testing scenarios.

### CROSS-REFERENCE TO RELATED APPLICATION

This application is a continuation application of PCT application No. PCT/CN2024/075429, filed on Feb. 2, 2024, which claims the priority to Chinese Patent Application No. 202310101391.5, filed on Feb. 10, 2023, the contents of all of which are incorporated herein by reference in their entirety.

### TECHNICAL FIELD

The present disclosure generally relates to the field of battery monitoring technology and, more particularly, relates to a battery physical self-discharge detection method, device, and medium.

### BACKGROUND

With the large-scale global promotion of new energy vehicles, the usage of a core component, power batteries, has become enormous. Batteries inherently exhibit self-discharge: one is physical self-discharge, mainly caused by microscopic physical short circuits and weakly correlated with temperature; and the other is chemical self-discharge, primarily due to spontaneous internal chemical reactions that lead to voltage drop and capacity degradation, which is strongly correlated with temperature. Self-discharge not only reduces a battery's capacity but also significantly affects a battery pack and cycle life. For the same chemical system at the same time, the extent of chemical self-discharge remains at a similar level and is relatively stable. However, the equivalent short-circuit resistance caused by internal metallic microparticles in physical self-discharge is random and unstable, while a battery's voltage drop shows continuous decline, making the battery's voltage drop a key detection target in self-discharge testing.

Currently, there are two common self-discharge testing methods: one is a conventional method for self-discharge measurement, and the other is a constant-voltage direct measurement method that measures a self-discharge current using a BT2152 self-discharge analyzer. The second method is more effective than the first one. It first measures a battery's open-circuit voltage Voc, and then stabilizes the BT2152 analyzer's output voltage at the initial Voc. If self-discharge exists, the discharge current Id equals the output current of the BT2152's constant-voltage source. The battery's self-discharge capability is judged based on the magnitude of Id. The measurement usually takes several minutes or several hours depending on the battery's characteristics.

However, this method cannot quickly distinguish whether a battery is physically self-discharging or chemically self-discharging. To distinguish, the battery needs to be placed at low temperature (to eliminate chemical self-discharge effects) and measured after temperature stabilization. It increases both testing time and costs of low-temperature control.

Therefore, there is an urgent need for a battery physical self-discharge detection method to solve the problem that the current self-discharge testing method is time-consuming and difficult to implement.

### SUMMARY

In one aspect of the present disclosure, a method for battery physical self-discharge detection includes outputting a corresponding short-duration pulse current to charge a battery under test according to preconfigured parameters, wherein the preconfigured parameters includes a pulse width, a pulse period, and amplitude, and the short-duration pulse current is a pulse current with a pulse period below a preset threshold; continuously measuring an open-circuit voltage of the battery under test for a preset time period and determining a voltage change trend; and when the voltage change trend shows continuous decline, determining the battery under test has physical self-discharge, and when the voltage change trend does not show continuous decline, determining the battery under test does not have physical self-discharge.

In another aspect of the present disclosure, a device for battery physical self-discharge detection includes a pulse test module used to output a corresponding short-duration pulse current to charge a battery under test according to prearranged pulse current parameters, wherein the prearranged pulse current parameters includes a pulse width, a pulse period, and amplitude; a voltage measurement module used to continuously collect an open-circuit voltage of the battery under test within a preset time period and determine a voltage change trend of the battery under test; and a result judgment module used to determine that the battery under test has physical self-discharge when the voltage change trend shows continuous decline, and determine the battery under test does not have physical self-discharge when the voltage change trend does not show continuous decline.

In another aspect of the present disclosure, a device for battery physical self-discharge detection includes one or more processors and a memory for storing computer programs that, when being executed, cause the one or more processors to perform the following: outputting a corresponding short-duration pulse current to charge a battery under test according to preconfigured parameters, wherein the preconfigured parameters includes a pulse width, a pulse period, and amplitude, and the short-duration pulse current is a pulse current with a pulse period below a preset threshold; continuously measuring an open-circuit voltage of the battery under test for a preset time period and determining a voltage change trend; and when the voltage change trend shows continuous decline, determining the battery under test has physical self-discharge, and when the voltage change trend does not show continuous decline, determining the battery under test does not have physical self-discharge.

Other aspects or embodiments of the present disclosure can be understood by those skilled in the art in light of the description, the claims, and the drawings of the present disclosure.

### BRIEF DESCRIPTION OF THE DRAWINGS

To better illustrate embodiments of this application, the following briefly introduces the accompanying drawings arranged for the embodiments. Obviously, the drawings in the following description are merely some embodiments of this application. For those of ordinary skill in the art, other drawings can be obtained from these drawings without creative effort.

FIG. 1 is a schematic diagram of an existing battery self-discharge detection method.

FIG. 2 is a flowchart of a battery physical self-discharge detection method provided by the present invention.

FIG. 3 is a schematic diagram of a battery physical self-discharge detection method provided by the present invention.

FIG. 4 is a simulated voltage diagram of a battery physical self-discharge detection method provided by the present invention.

FIG. 5 is a structural diagram of a battery physical self-discharge detection device provided by the present invention.

FIG. 6 is a structural diagram of another battery physical self-discharge detection device provided by the present invention.

### DETAILED DESCRIPTION

The technical solutions in the embodiments of this application will be clearly and completely described below with reference to the accompanying drawings in the embodiments. Obviously, the described embodiments are only part of the embodiments of this application, not all of them. Based on the embodiments in this application, all other embodiments obtained by those of ordinary skill in the art without creative work shall fall within the protection scope of this application.

The purpose of this application is to provide a battery physical self-discharge detection method, device, and medium to solve the problem that the current self-discharge measurement method takes a long time and is difficult to implement.

In order to solve the above technical problems, this application provides a battery physical self-discharge detection method. The detection method includes:
Outputting a corresponding short-duration pulse current to charge a battery under test according to preconfigured pulse current parameters, wherein the pulse current parameters include pulse width, pulse period, and amplitude, and the short-duration pulse current is a pulse current with a pulse period below a preset threshold;
Continuously measuring the open-circuit voltage of the battery under test for a preset time period and determining a voltage change trend; and
If the voltage change trend shows continuous decline, determining the battery under test has physical self-discharge; and if the voltage change trend does not show continuous decline, determining the battery under test does not have physical self-discharge.

Preferably, the detection method further includes:
Adjusting the pulse width, pulse period, and amplitude of the short-duration pulse current to charge the battery under test and measuring the open-circuit voltage of the battery under test; and
If the open-circuit voltage across the battery under test remains stable within one pulse period, determining corresponding pulse width, pulse period, and amplitude of the current short-duration pulse current to be the pulse current parameters.

Preferably, the detection method further includes:
Using the pulse current parameters corresponding to the battery under test and its physical self-discharge equivalent resistance as a training data set, and collecting a certain number of training data sets as a sample set;
Creating a machine learning model and training the machine learning model with the sample set to obtain a pulse current parameter prediction model; and
Determining pulse current parameters of another battery under test based on the physical self-discharge equivalent resistance of the other battery under test and through the pulse current parameter prediction model.

Preferably, when the model specifications or production process of the battery under test changes, the pulse current parameters are updated.

Preferably, determining the voltage change trend includes:
Determining the slope of a voltage change curve of the battery under test.

Correspondingly, determining that the battery under test has physical self-discharge if the voltage change trend shows a continuous decline and determining that the battery under test does not have physical self-discharge if the voltage change trend does not show a continuous decline includes:
If the slope of the voltage change curve is less than zero, determining the battery under test has physical self-discharge; and if the slope is greater than or equal to zero, determining the battery under test does not have physical self-discharge.

Preferably, the short-duration pulse current is generated by a pulse source with current precision at the nanoampere level.

Preferably, the detection method further includes:
Generating and sending out a test report for the battery under test. The test report includes a unique identification number of the battery under test, the voltage change curve, and physical self-discharge detection results.

To solve the above technical problems, this application also provides a battery physical self-discharge detection device. The detection device includes a pulse test module, a voltage measurement module, and a result judgment module.

The pulse test module is used to output a corresponding short-duration pulse current to charge a battery under test according to prearranged pulse current parameters. The pulse current parameters include pulse width, pulse period, and amplitude.

The voltage measurement module is used to continuously collect the open-circuit voltage of the battery under test within a preset time period and determine the voltage change trend of the battery under test.

The result judgment module is used to determine that the battery under test has physical self-discharge if the voltage change trend shows continuous decline, and determine no physical self-discharge exists if the voltage change trend does not show continuous decline.

Preferably, the battery physical self-discharge detection device further includes a first parameter determination module, a second parameter determination module, and a test report generation module.

The first parameter determination module is used to charge the battery under test by adjusting the pulse width, pulse period, and amplitude of the short-duration pulse current, and measure the open-circuit voltage of the battery under test. If the voltage across the battery under test remains stable within one pulse period, the pulse width, pulse period, and amplitude corresponding to the present short-duration pulse current are taken as the pulse current parameters.

The second parameter determination module is used to utilize the pulse current parameters corresponding to the battery under test and the physical self-discharge equivalent resistance of the battery under test as a training data set, and obtain a certain number of training data sets as a sample set; create a machine learning model and train the machine learning model using the training data in the sample set to obtain a pulse current parameter prediction model; and determine pulse current parameters based on the physical self-discharge equivalent resistance of another battery under test and through the pulse current parameter prediction model.

The test report generation module is used to generate and send out a test report of the battery under test. The test report includes a unique identification number of the battery under test, a voltage change curve, and physical self-discharge detection results.

To solve the above technical problems, this application also provides a battery physical self-discharge detection device that includes a memory and a processor.

The memory is used to store computer programs.

The processor is used to execute the computer programs to implement steps of the above illustrated battery physical self-discharge detection method.

To solve the above technical problems, this application also provides a computer-readable storage medium. Computer programs are stored in the computer-readable storage medium. The computer programs, when executed by a processor, cause the processor to implement steps of the above battery physical self-discharge detection method.

The battery physical self-discharge detection method provided in this application utilizes frequency response characteristics of battery physical self-discharge and chemical self-discharge to perform self-discharge testing. That is, the response time constant of physical self-discharge is less than microsecond (s) level, while the time constant of chemical self-discharge is usually at second (s) level. Therefore, when charging a battery with short-duration pulse current (e.g., a pulse period less than 100 ms), the equivalent chemical self-discharge resistance Red of the battery is large, and its influence on voltage may be ignored. At this time, if the battery has physical self-discharge, charges injected by the short-duration pulse current may be quickly consumed by the equivalent physical short-circuit resistance (physical self-discharge equivalent resistance) Rsd, and the measured open-circuit voltage of the battery may show an obvious downward trend and continue to decline. If there is no physical self-discharge phenomenon, the charges injected by the short-duration pulse current may gradually accumulate, and after a period of time (usually several minutes to more than ten minutes), the overall voltage may show an obvious rise. So by monitoring the voltage change trend, the battery under test is quickly screened for physical self-discharge phenomenon. This method needs a short testing time to detect whether a battery has physical self-discharge, and does not require low-temperature storage. It reduces the implementation difficulty and cost, and better meets the needs of actual battery self-discharge testing scenarios.

The battery physical self-discharge detection device and computer-readable storage media provided in this application correspond to the above methods and have the same effects.

The core of this application is to provide a method, a device, and media for battery physical self-discharge detection.

To enable those skilled in the art to better understand the solutions of this application, the following further describes this application in detail with reference to the accompanying drawings and specific implementations.

In current battery self-discharge detection, the main methods include the conventional self-discharge measurement method and a method that directly measures the self-discharge current under constant voltage through a self-discharge analyzer BT2152.

The conventional self-discharge measurement method mainly involves long-term storage of a battery (usually five days to one month), followed by measuring parameters such as open-circuit voltage, capacity, and state of charge to determine whether the battery has self-discharge. The conventional method has a long measurement cycle and low accuracy for battery self-discharge. The product turnover cycle is long, thereby requiring additional storage space. It is also prone to misjudgment and cannot distinguish whether battery's self-discharge is physical or chemical.

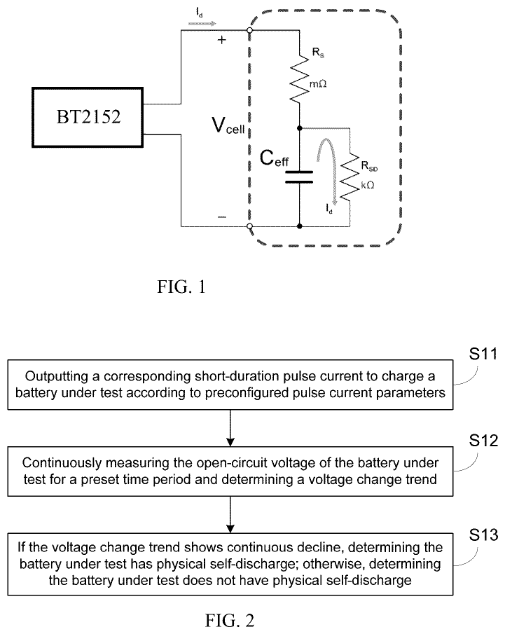

The detection principle of constant-voltage direct measurement of self-discharge current through a self-discharge analyzer BT2152 is shown in a simple model in FIG. 1. The self-discharge analyzer BT2152 is connected to both ends of a battery. The self-discharge analyzer BT2152 detects the open-circuit voltage Vcell of the battery, and then stabilizes the output voltage of the BT2152 at the initial open-circuit voltage Vcell of the battery. If the battery has self-discharge, its discharge current Id equals the output current of a constant-voltage source at BT2152. Based on the magnitude of Id, it can be determined whether the battery's self-discharge capability is qualified. The measurement generally takes only a few minutes or hours to complete. However, when distinguishing whether the battery's self-discharge is chemical or physical, this method requires low-temperature storage of the battery to eliminate the influence of chemical self-discharge. The voltage measurement is performed after the temperature stabilizes at a specified temperature. Consequently, it increases time and implementation cost of low-temperature control.

To solve the above problems, this application provides a battery physical self-discharge detection method that is fast and does not require low-temperature storage. As shown in FIG. 2, the method includes the following.

At S11, a corresponding short-duration pulse current is outputted to charge a battery under test according to prearranged pulse current parameters.

The pulse current parameters include pulse width, pulse period, and amplitude. The short-duration pulse current (Ipulse) is a pulse current with a pulse period smaller than a preset threshold.

The short-duration pulse current may be generated by a precision pulse source. Specific models and specifications of a pulse source are not limited in this embodiment. However, it should be noted that, based on the current common specifications and performance parameters of batteries under test, a pulse source generally needs to output short-duration pulse currents adjustable from microampere (μA) to milliampere (mA) levels, with a pulse width of less than 1 second (S), and a pulse period adjustable from microseconds (μS) to tens of seconds (S).

Further, it is preferable that the current accuracy of a pulse source reaches the nanoampere (nA) level to prevent the pulse source from significantly discharging the battery, which affects a subsequent judgment of whether physical self-discharge exists.

At S12, the open-circuit voltage of the battery under test is continuously measured for a preset duration and a voltage change trend is determined.

A preset duration generally ranges from a few minutes to more than ten minutes depending on the model, specifications, and specific parameters of a battery under test. The preset duration may be determined based on an actual battery under test, and this embodiment does not impose restrictions on it. A preset duration is set because when charging a battery with a short-duration pulse current, voltage change of the battery is not obvious. Therefore, continuous charging for a certain period and observation of battery voltage change during this time period are necessary to determine whether physical self-discharge occurs.

Collection of voltage across a battery may be achieved using a voltage measurement device such as a voltmeter. A voltmeter collects the open-circuit voltage of a battery. However, since the voltage detection accuracy required in this embodiment is relatively high, the voltmeter needs to have voltage accuracy within 100 μV and stability at the V μlevel.

That is, for the entire battery physical self-discharge detection system, as shown in FIG. 2, it may at least include a battery under test, a pulse source, and a voltmeter. Both the pulse source and the voltmeter are connected to the circuit. The pulse source is used to output a short-duration pulse current to charge a battery under test, while the voltmeter is used to measure the open-circuit voltage of the battery under test.

At S13, if the voltage change trend shows continuous decline, it is determined that the battery under test has physical self-discharge; and otherwise, i.e., the voltage change trend does not show continuous decline, it is determined that no physical self-discharge exists.

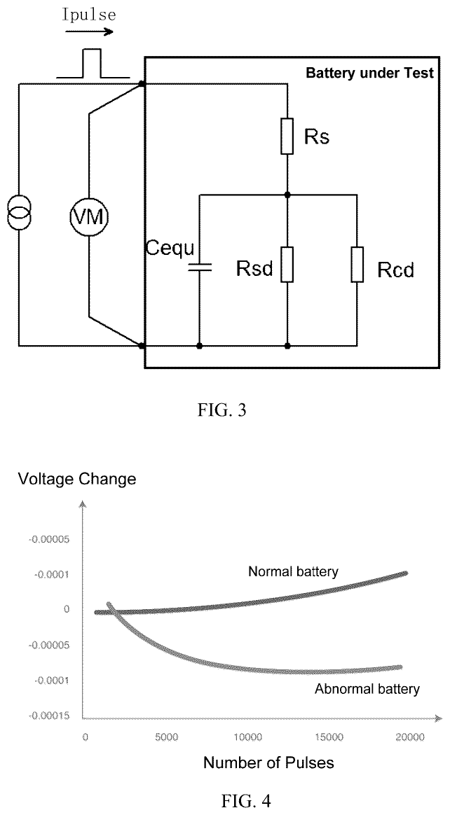

Regarding principles of the method provided in this embodiment for determining whether a battery has physical self-discharge, as shown in FIG. 3, the detection of physical self-discharge is achieved by connecting a pulse source and a high-precision voltmeter to both ends of the battery. The pulse source is used to output short-duration pulse currents for charging the battery. The high-precision voltmeter is used to collect the battery's open-circuit voltage for subsequent judgment. The battery may be viewed as internally including battery internal resistance Rs (generally in the milliohm range), an equivalent energy storage capacitor Cequ, physical self-discharge equivalent resistance Rsd (also called physical short-circuit resistance, generally in the kilohm range), and chemical self-discharge equivalent resistance Red (generally in the megaohm range).

When the pulse source outputs short-duration pulse currents (pulse period less than 100 mS), due to the different frequency response characteristics of physical and chemical self-discharge, e.g., the response time of physical self-discharge is less than microseconds while that of chemical self-discharge is typically in seconds, the chemical self-discharge equivalent resistance presents a high impedance state during charging with short-duration pulse currents (pulse period less than 100 ms), making its voltage influence negligible. Therefore, if the battery has no physical self-discharge, charges injected by the short-duration pulse currents may continuously accumulate, reflected as a steady increase of or nearly unchanged voltage across the battery. If the battery has physical self-discharge, charges injected by the short-duration pulse currents may be quickly consumed by the physical self-discharge equivalent resistance, causing a clear and sustained downward trend in the battery's terminal voltage.

FIG. 4 shows a forward simulation circuit diagram for defective product verification. A defective battery (i.e., one exhibiting physical self-discharge) is simulated by short-circuiting a normal battery with a 2 kΩ resistor, while a testing short-duration pulse current is set to 300 μA. From FIG. 4, it is evident that a normal battery's voltage remains stable with a slight upward trend, whereas the voltage of the 2 kΩ-shorted battery (simulating a defective product) shows continuous decline. The distinct difference in voltage trends between the two serves as a basis for determining whether a battery is a non-defective product regarding physical self-discharge.

Thus, based on the differing voltage change trends indicating the presence or absence of physical self-discharge, the method enables quick and convenient determination without requiring low-temperature storage.

Accordingly, as inferred from the above characteristics, when a battery has physical self-discharge issues, its open-circuit voltage should exhibit a continuous downward trend. This voltage change trend feature may be derived from a tested battery's voltage change curve. If the slope of the curve is less than zero (or negative), the tested battery may be identified as defective due to physical self-discharge. If the slope is greater than or equal to zero, it may indicate the battery is a good product with regard to physical self-discharge. It realizes the identification of battery physical self-discharge.

The battery physical self-discharge detection method provided in this embodiment utilizes different frequency response characteristics between chemical self-discharge and physical self-discharge of batteries. By employing a pulse source to output short-duration pulse currents to charge a battery, the influence of chemical self-discharge is eliminated. Through measuring the open-circuit voltage of the tested battery with a voltmeter and observing the voltage change trend, it may be determined whether the tested battery has physical self-discharge. It enables rapid screening of defective batteries with physical self-discharge. The entire method implementation process is fast, requiring only a few minutes to over ten minutes of charge accumulation to determine detection results based on an open-circuit voltage change trend of the battery. Additionally, there is no need for low-temperature storage of the battery. It saves time while also reducing the implementation difficulty and cost of the detection method, and better meets the needs of practical large-scale battery physical self-discharge testing.

As can be seen from the above embodiments, this application charges a tested battery with short-duration pulse currents and then detects an open-circuit voltage change trend of the tested battery to determine whether the current tested battery has physical self-discharge. Accordingly, the pulse current parameters of the short-duration pulse current may be key factors affecting the success rate and accuracy of this method.

In practical applications, pulse current parameters are mainly related to resistance values of the physical self-discharge equivalent resistance of a tested battery. Therefore, for tested batteries with different physical self-discharge equivalent resistances, short-duration pulse currents with different pulse current parameters are needed during detection. For a batch of batteries with the same model, specifications, and production process, their physical self-discharge equivalent resistances are similar, and the same set of pulse current parameters may be used.

In other words, whenever tested batteries are replaced with a batch of batteries of different model, specifications, or production processes, the pulse current parameters for detection need to be re-determined, which may be obtained through experimental adjustments. Specifically, the basis for selecting appropriate pulse current parameters as test parameters for a battery may be as follows:

Within one pulse period, the charge amount and discharge amount of the battery are equal.

That is, when charging the tested battery with short-duration pulse currents under these pulse current parameters, if the battery has no physical self-discharge issues, the open-circuit voltage should remain basically stable with these pulse currents, and the slope of the voltage change curve should approach zero. This represents an ideal detection scenario, facilitating identification of defective batteries with physical self-discharge.

Specifically, the above detection method further includes the following.

At S21, the battery under test is charged by adjusting the pulse width, pulse period, and amplitude of the short-duration pulse current. The open-circuit voltage of the battery under test is measured.

At S22, if the open-circuit voltage across the battery under test remains stable within one pulse period, the pulse width, pulse period, and amplitude corresponding to the current short-duration pulse current are taken as pulse current parameters.

The above embodiment illustrates that the current outputted by the pulse source is adjustable from A to mA levels, with a pulse width of less than iS, and an adjustable pulse period ranging from S to tens of seconds. Therefore, the pulse width, amplitude, and pulse period of the output pulse current are continuously adjusted, the battery's open-circuit voltage is observed, and whether the slope of the voltage change curve is close to zero is determined. A set of pulse current parameters with a slope close to zero and better effects may then be selected for subsequent physical self-discharge detection.

Further, if manual adjustment in the laboratory is required every time the pulse current parameters are updated, the efficiency of battery physical self-discharge detection may be significantly affected, which is unfavorable for industrialized batch detection of battery physical self-discharge. Therefore, based on the above embodiments, this embodiment also provides a preferred implementation solution. The detection method further includes the following.

At S31, pulse current parameters corresponding to the battery under test and its physical self-discharge equivalent resistance are used as a training data set. A certain number of training data sets are collected as a sample set.

Training data for a sample set may be obtained by the laboratory manual adjustment method described in the above embodiment. That is, when the data of a sample set is insufficient, ideal pulse current parameters may be determined through manual adjustments in the laboratory. When enough data is determined in the laboratory in the past, the pulse current parameters obtained in the past and their corresponding battery physical self-discharge equivalent resistance values may be used together as sample set data for subsequent model training.

At S32, a machine learning model is created. The machine learning model is trained using training data in the sample set to obtain a pulse current parameter prediction model.

It is easy to understand that a training set includes multiple sets of training data, and each set of training data consists of current pulse parameters and a corresponding physical self-discharge resistance value. The current pulse parameters and corresponding physical self-discharge resistance values may be used as a model's input and output, respectively, to perform model training.

It should be noted that specific learning methods of the machine learning model are not limited in this embodiment. Moreover, machine learning already has many mature applications and methods. Therefore, methods of using sample set data to train a machine learning model for predicting pulse current parameters are well-known to those skilled in the art, and this embodiment will not elaborate further here.

At S33, pulse current parameters are determined based on the physical self-discharge equivalent resistance of another battery under test and through the pulse current parameter prediction model.

In the sample set data, current pulse parameters and a physical self-discharge equivalent resistance value form a corresponding dataset, which may serve as the input and output of a pulse current parameter prediction model, respectively. After the physical self-discharge equivalent resistance value of a batch of batteries to be tested are obtained, the resistance value may be used as the input to acquire pulse current parameters outputted by the prediction model, which may then serve as pulse current parameters for subsequent testing. Due to the nature of machine learning, the larger the sample set data, the more accurate the prediction results. This allows for continuous optimization of pulse current parameter prediction during actual use, making it suitable for industrial-scale batch detection of battery physical self-discharge. While the detection efficiency is improved, the accuracy of detection is also better guaranteed.

This embodiment specifically illustrates the method for determining pulse current parameters. When sample data is insufficient, manual adjustment in the laboratory may be employed to adjust the pulse width, amplitude, and pulse period of a pulse current, ensuring that the open-circuit voltage of a battery remains essentially stable. This prevents interference from other factors on the continuously declining voltage trend of a defective battery with physical self-discharge, thereby improving the accuracy of detection results. When sufficient historical data is available as sample set data, a prediction model may be trained using machine learning methods. Subsequently, by inputting a physical self-discharge equivalent resistance value of a battery under test, corresponding current pulse parameters may be quickly obtained for subsequent physical self-discharge detection. It not only enhances detection efficiency but also improves the accuracy of pulse current parameter prediction as historical data accumulates. The method well adapts to characteristics of industrial-scale batch battery physical self-discharge detection scenarios and ensures more reliable detection accuracy.

Furthermore, this embodiment also provides a preferred implementation solution. After detecting physical self-discharge results of a battery under test, the above detection method additionally includes the following.

At S14, a test report for the battery under test is generated and sent out.

The test report includes, but is not limited to, a unique identification number of the battery under test, a voltage change curve, and physical self-discharge detection results.

An existing serial number of a battery under test may be used as the unique identification number of the battery, such as a factory serial number, etc. A unique identification number of a battery under test may also be established during a detection process, as long as it serves the purpose of distinguishing different batteries under test. This embodiment does not impose excessive restrictions on this. A voltage change curve may be used for review of a detection method. A physical self-discharge detection result directly informs relevant personnel whether a battery under test has physical self-discharge issues, facilitating statistical analysis of detection results.

Outputs of test reports may have multiple output manners. For example, a corresponding test report may be outputted after testing a certain number of batteries under test. Alternatively, a test report corresponding to a specific time period may be outputted after certain duration of testing. Alternatively, whenever a batch of batteries under test is changed or pulse current parameters are updated, a test report may be outputted for the previous batch of batteries or previously tested batteries. In actual battery physical self-discharge detection, the output logic of test reports may adopt any of the above examples or be determined according to actual needs. This embodiment does not impose restrictions on this.

The preferred solution provided in this embodiment generates test reports corresponding to detection results, which facilitates relevant personnel promptly obtaining specific detection results. It also facilitates statistical analysis of parameters such as yield rate and defective rate for the current batch of batteries, and better meets the needs of actual battery testing.

In the above embodiments, a detailed description is given for a battery physical self-discharge detection method. This application also provides corresponding embodiments for battery physical self-discharge detection devices. It should be noted that embodiments of the devices are described from two perspectives in this application: one based on functional modules and the other based on hardware.

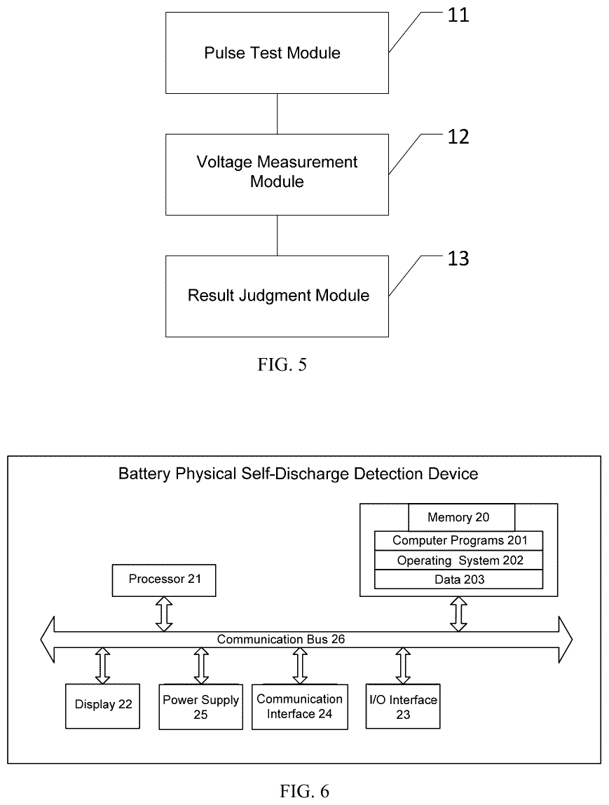

From the perspective of functional modules, as shown in FIG. 5, this embodiment provides a battery physical self-discharge detection device. The detection device includes a pulse test module 11, a voltage measurement module 12, and a result judgment module 13.

The pulse test module 11 is used to output corresponding short-duration pulse currents to charge a battery under test according to preconfigured pulse current parameters. The prearranged pulse current parameters include pulse width, pulse period, and amplitude.

The voltage measurement module 12 is used to continuously collect the open-circuit voltage of the battery under test within a preset duration and determine a voltage change trend of the battery under test.

The result judgment module 13 is used to determine that the battery under test has physical self-discharge if the voltage change trend shows continuous decline, and otherwise (i.e., the voltage change trend does not show continuous decline), determine no physical self-discharge exists.

Preferably, the above battery physical self-discharge detection device further includes a first parameter determination module, a second parameter determination module, and a test report generation module.

The first parameter determination module is used to charge a battery under test by adjusting the pulse width, pulse period, and amplitude of the short-duration pulse current, and measure the open-circuit voltage of the battery under test. If the open-circuit voltage across the battery under test remains stable within one pulse period, then the pulse width, pulse period, and amplitude corresponding to the current short-duration pulse current are taken as pulse current parameters.

The second parameter determination module is used to utilize the pulse current parameters corresponding to the battery under test and physical self-discharge equivalent resistance of the battery under test as a training data set, and obtain a certain number of training data sets as a sample set; create a machine learning model and train the machine learning model using the training data in the sample set to obtain a pulse current parameter prediction model; and determine pulse current parameters based on the physical self-discharge equivalent resistance of a battery under test and through the pulse current parameter prediction model.

The test report generation module is used to generate and send out a test report of the battery under test. The test report includes a unique identification number of the battery under test, a voltage change curve, and physical self-discharge detection results.

Since embodiments of the device part correspond to embodiments of the method part, descriptions of embodiments of the device part may refer to that of embodiments of the method part, which will not be repeated here.

FIG. 6 shows a structural diagram of a battery physical self-discharge detection device according to another embodiment of this application. As shown in FIG. 6, the battery physical self-discharge detection device includes a memory 20 and a processor 21.

The memory 20 is used to store computer programs.

The processor 21 is used to execute the computer programs to implement steps of the battery physical self-discharge detection method described in the above embodiments.

The battery physical self-discharge detection device provided in this embodiment may include, but is not limited to, devices such as a tablet, a laptop, or a desktop computer.

The processor 21 may include one or more processing cores, such as a 4-core processor or an 8-core processor. The processor 21 may be implemented using at least one of the following hardware forms: Digital Signal Processor (DSP), Field-Programmable Gate Array (FPGA), or Programmable Logic Array (PLA). The processor 21 may also include a main processor and a coprocessor. The main processor is used to process data in an awake state and is also called a Central Processing Unit (CPU). The coprocessor is a low-power processor used to process data in a standby state. In some embodiments, the processor 21 may integrate a Graphics Processing Unit (GPU), which is responsible for rendering and drawing content to be displayed on a screen. In some embodiments, the processor 21 may also include an Artificial Intelligence (AI) processor for handling machine learning computations.

The memory 20 may include one or more computer-readable storage media, which may be non-transitory. The memory 20 may also include high-speed random-access memory and non-volatile memory, such as one or more disk storage devices or flash storage devices. In this embodiment, the memory 20 is at least used to store the following computer programs 201. When loaded and executed by the processor 21, the computer programs 201 may implement steps of the battery physical self-discharge detection method disclosed in any of the preceding embodiments. Additionally, the resources stored in the memory 20 may also include an operating system 202 and data 203 among others. The storage method may be temporary or permanent. The operating system 202 may include Windows, Unix, Linux, etc. The data 203 may include, but is not limited to, a battery physical self-discharge detection method, etc.

In some embodiments, the battery physical self-discharge detection device may further include a display screen 22, an input/output (I/O) interface 23, a communication interface 24, a power supply 25, and a communication bus 26.

Those skilled in the art may understand that the structure shown in FIG. 6 does not limit the battery physical self-discharge detection device and may include more or fewer components than those illustrated.

A battery physical self-discharge detection device provided in the embodiments of this application includes a memory and a processor. When the processor executes programs stored in the memory, the processor may implement the following method: the battery physical self-discharge detection method.

Finally, this application also provides an embodiment corresponding to a computer-readable storage medium. The computer-readable storage medium stores computer programs, which, when executed by a processor, implement the steps described in the method embodiments illustrated above.

It is understandable that if the method in the above embodiments is implemented in a form of a software functional unit and sold or used as an independent product, the method may be stored in a computer-readable storage medium. Based on this understanding, the technical solution of this application, in essence or a part of it contributing to the prior art, or all or part of the technical solution, may be embodied in the form of a software product. This computer software product is stored in a storage medium and includes instructions for executing all or part of the steps of the methods described in the various embodiments of this application. The aforementioned storage media include various media that may store program codes, such as USB flash drives, mobile hard disks, read-only memory (ROM), random-access memory (RAM), magnetic disks, or optical disks.

The above provides a detailed introduction to a battery physical self-discharge detection method, device, and medium provided by this application. The various embodiments in the specification are described in a progressive manner, with each embodiment focusing on the differences from other embodiments. The same or similar parts between the embodiments may be referred to each other. For devices disclosed in the embodiments, since they correspond to the methods disclosed in the embodiments, the description is relatively simple, and the relevant parts may be referred to the method section for details. It should be noted that for those of ordinary skill in the technical field, without departing from the principles of this application, several improvements and modifications may be made to this application, and these improvements and modifications also fall within the protection scope of the claims of this application.

It should also be noted that in this specification, relational terms such as first and second are only used to distinguish one entity or operation from another entity or operation, and do not necessarily require or imply any actual relationship or order between these entities or operations. Moreover, the terms “include,” “comprise,” or any other variation thereof are intended to cover non-exclusive inclusion, so that a process, method, article, or device that includes a series of elements not only includes those elements but also includes other elements not explicitly listed, or further includes elements inherent to such process, method, article, or device. Without further limitation, an element defined by the phrase “including a . . . ” does not exclude the presence of additional identical elements in the process, method, article, or device that includes the element.

What is claimed is:

1. A method for battery physical self-discharge detection, comprising:
outputting a corresponding short-duration pulse current to charge a battery under test according to preconfigured parameters, the preconfigured parameters including a pulse width, a pulse period, and amplitude, and the short-duration pulse current being a pulse current with a pulse period below a preset threshold;
continuously measuring an open-circuit voltage of the battery under test for a preset time period and determining a voltage change trend; and
when the voltage change trend shows continuous decline, determining the battery under test has physical self-discharge; and when the voltage change trend does not show continuous decline, determining the battery under test does not have physical self-discharge.

2. The method according to claim 1, further comprising:
adjusting a pulse width, a pulse period, and amplitude of the short-duration pulse current to charge the battery under test and measuring the open-circuit voltage of the battery under test; and
when the open-circuit voltage of the battery under test remains stable within one pulse period, determining a pulse width, a pulse period, and amplitude of a corresponding current short-duration pulse current to be pulse current parameters of the battery under test.

3. The method according to claim 2, further comprising:
using the pulse current parameters corresponding to the battery under test and physical self-discharge equivalent resistance of the battery under test as a training data set, and collecting a predetermined number of training data sets as a sample set;
creating a machine learning model and training the machine learning model using training data in the sample set to obtain a pulse current parameter prediction model; and
determining pulse current parameters of another battery under test based on physical self-discharge equivalent resistance of the other battery under test and through the pulse current parameter prediction model.

4. The method according to claim 3, wherein when model specifications or a production process of the battery under test changes, the pulse current parameters of the battery under test are updated.

5. The method according to claim 1, wherein determining the voltage change trend comprises:
determining a slope of a voltage change curve of the battery under test, wherein determining that the battery under test has physical self-discharge when the voltage change trend shows a continuous decline and determining that the battery under test does not have physical self-discharge when the voltage change trend does not show a continuous decline includes:
when the slope of the voltage change curve is less than zero, determining the battery under test has physical self-discharge; and when the slope of the voltage change curve is greater than or equal to zero, determining the battery under test does not have physical self-discharge.

6. The method according to claim 1, wherein the short-duration pulse current is generated by a pulse source with current precision at a nanoampere level.

7. The method according to claim 5, further comprising:
generating and sending out a test report for the battery under test, the test report including a unique identification number of the battery under test, the voltage change curve, and a physical self-discharge detection result.

8. A device for battery physical self-discharge detection, comprising:
a pulse test module used to output a corresponding short-duration pulse current to charge a battery under test according to prearranged pulse current parameters, the prearranged pulse current parameters including a pulse width, a pulse period, and amplitude;
a voltage measurement module used to continuously collect an open-circuit voltage of the battery under test within a preset time period and determine a voltage change trend of the battery under test; and
a result judgment module used to determine that the battery under test has physical self-discharge when the voltage change trend shows continuous decline, and determine the battery under test does not have physical self-discharge when the voltage change trend does not show continuous decline.

9. The device according to claim 8, further comprising:
a first parameter determination module used to charge the battery under test by adjusting a pulse width, a pulse period, and amplitude of the short-duration pulse current, and measure the open-circuit voltage of the battery under test.

10. The device according to claim 9, wherein when the open-circuit voltage of the battery under test remains stable within one pulse period, a pulse width, a pulse period, and amplitude of a corresponding current short-duration pulse current are determining to be pulse current parameters of the battery under test.

11. The device according to claim 10, further comprising:
a second parameter determination module used to utilize the pulse current parameters corresponding to the battery under test and physical self-discharge equivalent resistance of the battery under test as a training data set, and obtain a preset number of training data sets as a sample set; create a machine learning model; and train the machine learning model using training data in the sample set to obtain a pulse current parameter prediction model.

12. The device according to claim 11, wherein the second parameter determination module is further used to determine pulse current parameters of another battery based on physical self-discharge equivalent resistance of the other battery under test and through the pulse current parameter prediction model.

13. The device according to claim 8, further comprising:
a test report generation module used to generate and send out a test report of the battery under test, the test report including a unique identification number of the battery under test, a voltage change curve, and physical self-discharge detection results.

14. A device for battery physical self-discharge detection, comprising:
one or more processors; and
a memory for storing computer programs that, when being executed, cause the one or more processors to perform:
outputting a corresponding short-duration pulse current to charge a battery under test according to preconfigured parameters, the preconfigured parameters including a pulse width, a pulse period, and amplitude, and the short-duration pulse current being a pulse current with a pulse period below a preset threshold;
continuously measuring an open-circuit voltage of the battery under test for a preset time period and determining a voltage change trend; and
when the voltage change trend shows continuous decline, determining the battery under test has physical self-discharge; and when the voltage change trend does not show continuous decline, determining the battery under test does not have physical self-discharge.

15. The device according to claim 14, wherein the one or more processors are further configured to perform:
adjusting a pulse width, a pulse period, and amplitude of the short-duration pulse current to charge the battery under test and measuring the open-circuit voltage of the battery under test; and
when the open-circuit voltage of the battery under test remains stable within one pulse period, determining a pulse width, a pulse period, and amplitude of a corresponding current short-duration pulse current to be pulse current parameters of the battery under test.

16. The device according to claim 15, wherein the one or more processors are further configured to perform:
using the pulse current parameters corresponding to the battery under test and physical self-discharge equivalent resistance of the battery under test as a training data set, and collecting a predetermined number of training data sets as a sample set;
creating a machine learning model and training the machine learning model using training data in the sample set to obtain a pulse current parameter prediction model; and
determining pulse current parameters of another battery under test based on physical self-discharge equivalent resistance of the other battery under test and through the pulse current parameter prediction model.

17. The device according to claim 16, wherein when model specifications or a production process of the battery under test changes, the pulse current parameters of the battery under test are updated.

18. The device according to claim 14, wherein the one or more processors are further configured to perform:
determining a slope of a voltage change curve of the battery under test, wherein determining that the battery under test has physical self-discharge when the voltage change trend shows a continuous decline and determining that the battery under test does not have physical self-discharge when the voltage change trend does not show a continuous decline includes:
when the slope of the voltage change curve is less than zero, determining the battery under test has physical self-discharge; and when the slope of the voltage change curve is greater than or equal to zero, determining the battery under test does not have physical self-discharge.

19. The device according to claim 14, wherein the short-duration pulse current is generated by a pulse source with current precision at a nanoampere level.

20. A non-transitory computer readable storage medium containing computer programs that, when being executed, cause at least one processor to perform the method according to claim 1.
